(19) United States
(12) Patent Application Publication
(10) Pub. No.: US 2011/0227609 A1
(43) Pub. Date: Sep. 22, 2011

(54) SEMICONDUCTOR INTEGRATED CIRCUIT CAPABLE OF EVALUATING THE CHARACTERISTICS OF A TRANSISTOR

(75) Inventor: Natsuki Kushiyama, Kawasaki-shi (JP)

(73) Assignee: KABUSHIKI KAISHA TOSHIBA, Tokyo (JP)

(21) Appl. No.: 13/050,078

(22) Filed: Mar. 17, 2011

(30) Foreign Application Priority Data
Mar. 19, 2010 (JP) 2010-064739

(51) Int. Cl. H03K 5/00; H03L 7/00

(52) U.S. Cl. 327/97; 327/141

(57) ABSTRACT

According to one embodiment, a test circuit comprises a function block, a test circuit, and a signal generation circuit. The test circuit is arranged in an area close to the function block having a plurality of transistors. The test circuit comprises a first flip-flop circuit, a second flip-flop circuit, and a logic circuit connected between the output of the first flip-flop circuit and the input of the second flip-flop circuit. The signal generation circuit generates clock pulses including a first clock pulse and a second clock pulse. The signal generation circuit is capable of controlling a pulse interval between the first clock pulse and the second clock pulse. In a test, the first flip-flop circuit outputs data in synchronization with the first clock pulse of the signal generation circuit and the second flip-flop circuit latches data in synchronization with the second clock pulse of the signal generation circuit.

### CROSS-REFERENCE TO RELATED APPLICATIONS

This application is based upon and claims the benefit of priority from Japanese Patent Application No. 2010-064739, filed Mar. 19, 2010; the entire contents of which are incorporated herein by reference.

### FIELD

Embodiments described herein relate generally to a semiconductor integrated circuit, and more particularly to a semiconductor integrated circuit capable of evaluating the characteristics of a transistor.

### BACKGROUND

When the characteristics of a transistor, including a current driving capability, were tested, the characteristics of a transistor on a chip were estimated by evaluating the characteristics of a transistor test element group (TEG) mounted on a dicing line.

However, with the miniaturization of elements, the characteristics of transistors on a chip differ depending on the position on the chip. Therefore, it is becoming difficult to test a transistor TEG as a representative of the transistors on a dicing line and, on the basis of the test result, estimate the characteristics of the transistors on the chip. Specifically, the characteristics of the transistor TEG on the dicing line do not necessarily represent the characteristics of all the transistors on the chip.

### BRIEF DESCRIPTION OF THE DRAWINGS

FIG. 1 is a schematic diagram of a semiconductor chip acting as a semiconductor device according to an embodiment;

FIG. 2 is a schematic diagram of an example of the PLL circuit shown in FIG. 1;

FIG. 3 is a circuit diagram of an example of a test circuit;

FIG. 4 is a circuit diagram of another example of the text circuit;

FIG. 5 is a table to explain the operation of FIG. 4;

FIG. 6 is a circuit diagram of another example of the test circuit;

FIG. 7 is a table to explain the operation of FIG. 6;

FIG. 8 is a flowchart to explain an example of the operation of the test device; and

FIG. 9 is a schematic diagram of a modification of the semiconductor device according to the embodiment.

### DETAILED DESCRIPTION

In general, according to one embodiment, a test circuit comprises a function block, a test circuit, and a signal generation circuit. The function block comprises a plurality of transistors. The test circuit is arranged in an area close to the function block. The test circuit comprises a first flip-flop circuit, a second flip-flop circuit, and a logic circuit connected between the output of the first flip-flop circuit and the input of the second flip-flop circuit. The signal generation circuit generates clock pulses including a first clock pulse and a second clock pulse. The signal generation circuit is capable of controlling a pulse interval between the first clock pulse and the second clock pulse. In a test, the first flip-flop circuit outputs data in synchronization with the first clock pulse of the signal generation circuit and the second flip-flop circuit latches data in synchronization with the second clock pulse of the signal generation circuit.

As described above, the characteristics of the transistor TEG on the dicing line do not necessarily represent the characteristics of all the transistors on the chip. Therefore, it is conceivable that the TEG is provided inside the chip. The TEG has pads connected to the gate, drain, source, and back gate of a transistor in a one-to-one correspondence. A test is conducted by bringing probes into contact with the pads. Since the TEG has at least four pads and therefore occupies a large area, it is practically difficult to provide a plurality of TEGs on a chip.

Accordingly, in the present circumstances, it is difficult to evaluate the characteristics of a transistor in an arbitrary position on the chip. Therefore, if the characteristics of a transistor in an arbitrary position on the chip can be evaluated after the semiconductor chip has been packaged, this is expected to be helpful in analyzing a defective product.

Hereinafter, the embodiment will be explained with reference to the accompanying drawings.

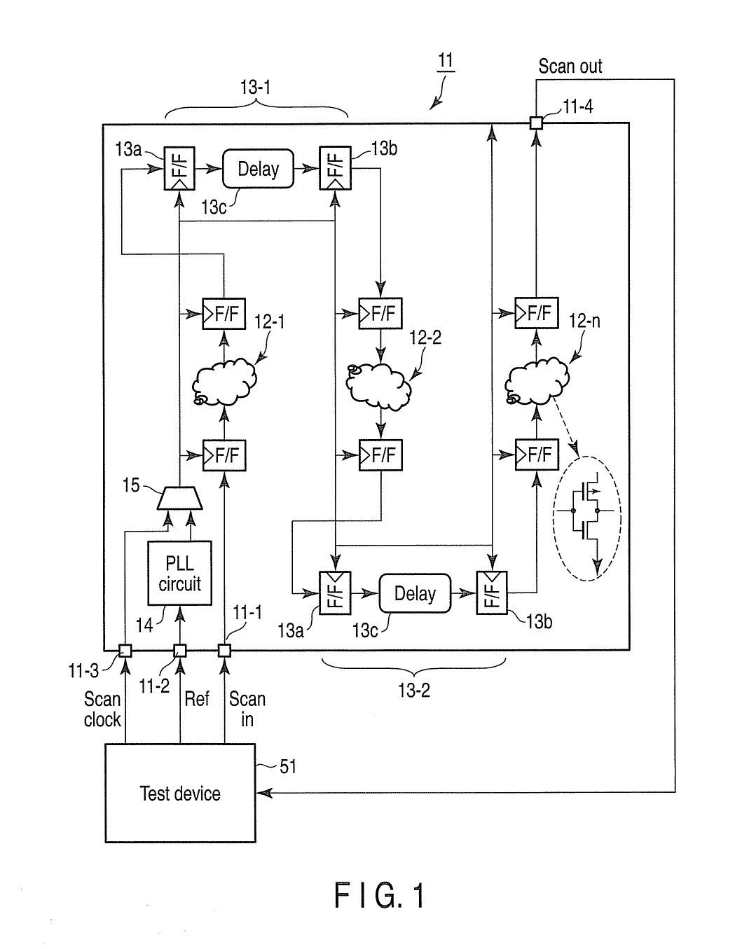

FIG. 1 shows a configuration of a semiconductor device according to the embodiment at the time of a test. A semiconductor chip 11 comprises a plurality of function blocks 12-1, 12-2, . . . , 12-n. Each of the function blocks 12-1, 12-2, . . . , 12-n is composed of, for example, many combinational circuits made up of a plurality of transistors and others (not shown). In a normal operation, the function blocks 12-1, 12-2, . . . , 12-n carry out a specific operation on the basis of, for example, a clock signal and input data.

At each of the input end and output end of each of the function blocks 12-1, 12-2, . . . , 12-n, there is provided, for example, a flip-flop circuit (F/F). Each of the flip-flop circuits (F/Fs) has a scan terminal (clock signal input terminal). A clock signal selected by a multiplexer 15 is supplied to the scan terminal of each of the flip-flop circuits (F/Fs).

Test circuits 13-1, 13-2 are arranged in arbitrary positions of the semiconductor chip 11. For example, when the characteristics (e.g., current driving capability, delay) of a transistor constituting a function block are needed, the test circuits 13-1, 13-2 are arranged in an area near the function block. Test circuit 13-1 is provided between, for example, function blocks 12-1 and 12-2. Test circuit 13-2 is provided between, for example, function blocks 12-2 and 12-n.

Each of the test circuits 13-1, 13-2 is composed of, for example, a first and a second flip-flop circuit 13a, 13b and a logic circuit including at least one inverter circuit arranged between the first and second flip-flop circuits 13a and 13b. More specifically, the logic circuit 13c is connected between the output of the first flip-flop circuit 13a and the input of the second flip-flop circuit 13b.

In addition, the semiconductor chip 11 has at least input terminals 11-1, 11-2, 11-3 and an output terminal 11-4. In a test, a test device 51 is connected to the input terminals 11-1, 11-2, 11-3 and output terminal 11-4. The input terminal 11-1 receives test data (Scan in) supplied from the test device 51 and supplies the test data to the flip-flop circuit (F/F) connected to the input stage of function block 12-1. The input terminal 11-2 receives a reference clock signal (Ref) supplied from the test device 51 and supplies the signal to a phase-locked loop (PLL) circuit 14. The input terminal 11-3 receives a scan clock signal (Scan clock) supplied from the test device 51 and supplies the signal to the multiplexer 15. The output terminal 11-4 receives a test result (Scan out) from the semiconductor chip 11 and supplies the result to the test device 51.

The PLL circuit 14 outputs a first and a second clock pulse CL1, CL2 described later. The PLL circuit 14 can adjust the pulse interval T between the first clock pulse CL1 and the second clock pulse CL2. The first and second clock pulses CL1, CL2 output from the PLL circuit 14 are supplied to the multiplexer 15.

In a test, when test data (Scan in) supplied from the test device is set in each of the flip-flop circuits (F/Fs), the multiplexer 15 selects a scan clock signal (Scan clock) supplied from the text device 51. Moreover, in a test, test data set in the first flip-flop circuit 13a is output to a logic circuit 13c and the second flip-flop circuit 13b is caused to latch the data output from the logic circuit 13c, that is, when the characteristics (current driving capability, delay, and the like) of the logic circuit 13c are tested, the multiplexer 15 selects the first and second clock pulses CL1, CL2 supplied from the PLL circuit 14.

The test circuits 13-1, 13-2 may not be connected to the function blocks and only the test circuits 13-1, 13-2 may be arranged near the function blocks.

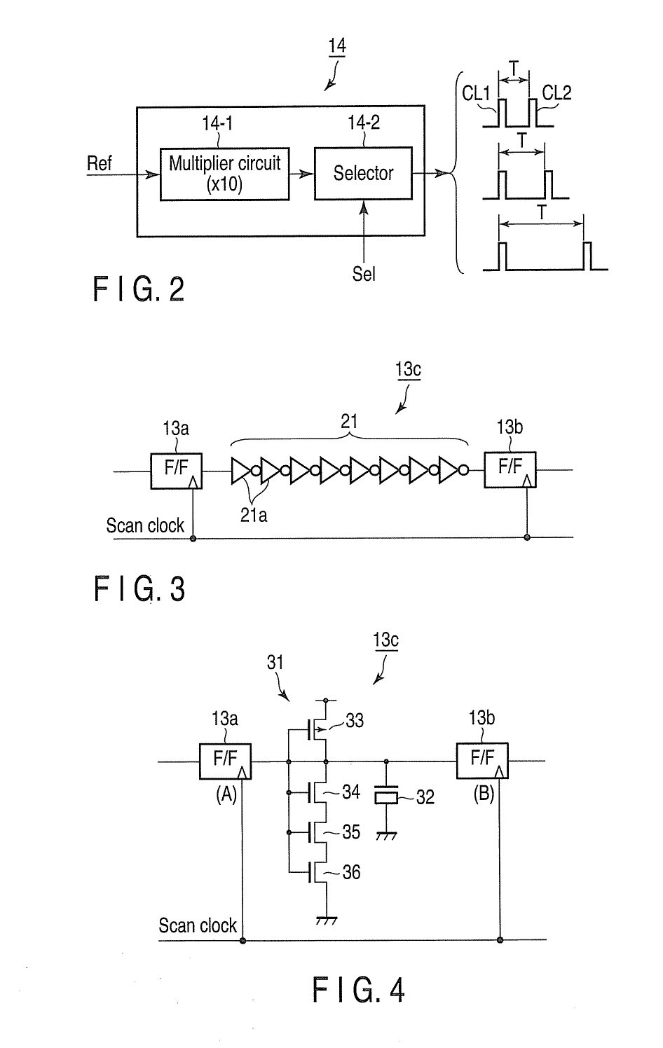

Next, the PLL circuit (signal generation circuit) will be explained with reference to FIG. 2. FIG. 2 shows an example of the PLL circuit 14 acting as a signal generation circuit. In FIG. 2, a phase comparator circuit, a voltage control oscillator, and others constituting the main part of the PLL circuit are omitted. The PLL circuit 14 includes, for example, a multiplier circuit 14-1 and a selector 14-2.

In a test, the multiplier circuit 14-1 receives a reference clock signal (Ref) supplied from the test device 51 and multiplies the reference clock signal (Ref) so as to produce a clock signal whose frequency is, for example, 10 times that of the reference clock signal. The output signal of the multiplier circuit 14-1 is supplied to, for example, the selector 14-2. On the basis of a selection signal (Sel) supplied from, for example, the test device 51, the selector 14-2 selects two clock signals from the signals supplied from the multiplier circuit 14-1 and outputs a first and a second clock pulse Cl1, CL2. That is, when the selection signal (Sel) is being supplied, the selector 14-2 selects the first and second clock pulses CL1, CL2 from the output signals of the multiplier circuit 14-1 and outputs the clock pulses CL1, CL2 consecutively. Let the interval between the first and second clock pulses CL1, CL2 be a pulse interval T.

In a test, the pulse interval T can be adjusted by adjusting the frequency of the reference clock signal (Ref). For example, when the frequency of the reference clock signal (Ref) is low, the pulse interval T is long. The pulse interval T can be made shorter by increasing the frequency of the reference clock signal (Ref). In this way, controlling the frequency of the reference clock signal (Ref) makes it possible to adjust the pulse interval T between the first and second clock pulses CL1, CL2.

In the explanation, the pulse interval T has been adjusted by controlling the frequency of the reference clock signal with the multiple number at the multiplier circuit 14-1 being kept constant. Alternatively, the pulse interval T between the first and second clock pulses CL1, CL2 may be adjusted by controlling the multiple number at the multiplier circuit 14-1 with the frequency of the reference clock signal being kept constant. The multiple number at the multiplier 14-1 may be controlled so as to be set to, for example, 11 times, 12 times, . . . .

Next, the test circuit will be explained with reference to FIG. 3. FIG. 3 shows an example of the test circuit. As shown in FIG. 3, the logic circuit 13c is composed of an inverter chain 21 including, for example, a plurality of inverter circuits 21a connected in series. The input of the inverter chain 21 is connected to the output of the first flip-flop circuit 13a and the output of the inverter chain 21 is connected to the input of the second flip-flop circuit 13b.

Next, with this configuration, an operation in a test will be explained. In a test, first, for example, data “0” is set in the first flip-flop circuit 13a in synchronization with a scan clock signal and, for example, data “1” is set in the second flip-flop circuit 13b.

Next, a first clock pulse CL1 is input to the first flip-flop circuit 13a and second flip-flop circuit 13b, causing data “0” set in the first flip-flop circuit 13a to be output to the inverter chain 21 in synchronization with the first clock pulse CL1.

Furthermore, the second clock pulse CL2 is input to the first flip-flop circuit 13a and second flip-flop circuit 13b, causing the second flip-flop circuit 13b to latch data output from the inverter chain 21 in synchronization with the second clock pulse CL2. At this time, when the delay of the inverter circuit 21a included in the inverter chain 21 is sufficiently small, data “0” output from the first flip-flop circuit 13a propagates through the inverter chain 21 and is latched in the second flip-flop circuit 13b in synchronization with the second clock pulse CL2. As a result, the data held in the second flip-flop circuit 13b is changed from data “1” to data “0”.

When the delay of the inverter circuit 21a included in the inverter chain is large, the second clock pulse CL2 is input to the second flip-flop circuit 13b before data “0” output from the first flip-flop circuit 13a reaches the second flip-flop circuit 13b. As a result, the second flip-flop circuit 13b does not latch data “0” output from the first flip-flop circuit 13a. Therefore, the data held in the second flip-flop circuit 13b remains at data “1”.

Then, the pulse interval T between the first clock pulse CL1 and second clock pulse CL2 is adjusted and the operations as described above are carried out. For example, the above operations are performed as the pulse interval T is changed so as to decrease gradually. As a result, the delay of the inverter circuit 21a included in the inverter chain 21 can be evaluated by monitoring the pulse interval T in which the data in the second flip-flop circuit 13b does not change.

The number of inverter circuits is not limited to an even number and may be an odd number. When the number of inverter circuits is an even number, different data items are set to the first and second flip-flop circuits 13a, 13b. When the number of inverters is an odd number, the same data item is set to the first and second flip-flop circuits 13a, 13b.

With the test circuit including the inverter chain 21 shown in FIG. 3, the delay of the transistors included in a function block arranged near the test circuit can be evaluated.

Next, an example of the test circuit will be explained with reference to FIG. 4. FIG. 4 shows a test circuit for evaluating the current driving capability of an NMOS.

The logic circuit 13c of the test circuit is composed of an inverter circuit 31 and an NMOS capacitor 32. The inverter circuit 31 is composed of, for example, a p-channel transistor 33 connected between a power supply and ground and, for example, three NMOSs 34, 35, and 36. The number of NMOSs is not limited to three. That is, the number of NMOSs has only to be set so as to achieve an operation speed at which the operation of the inverter circuit 31 and NMOS capacitor 32 can be evaluated sufficiently in the pulse interval between the first and second clock pulses CL1, CL2.

The gates of the PMOS 33 and NMOSs 34, 35, 36 are connected to the output end of the first flip-flop circuit 13a. The NMOS capacitor 32 is connected between the connection node of PMOS 33 and NMOS 34 and ground. The connection node of PMOS 33 and NMOS 34 is further connected to the input end of the second flip-flop circuit 13b.

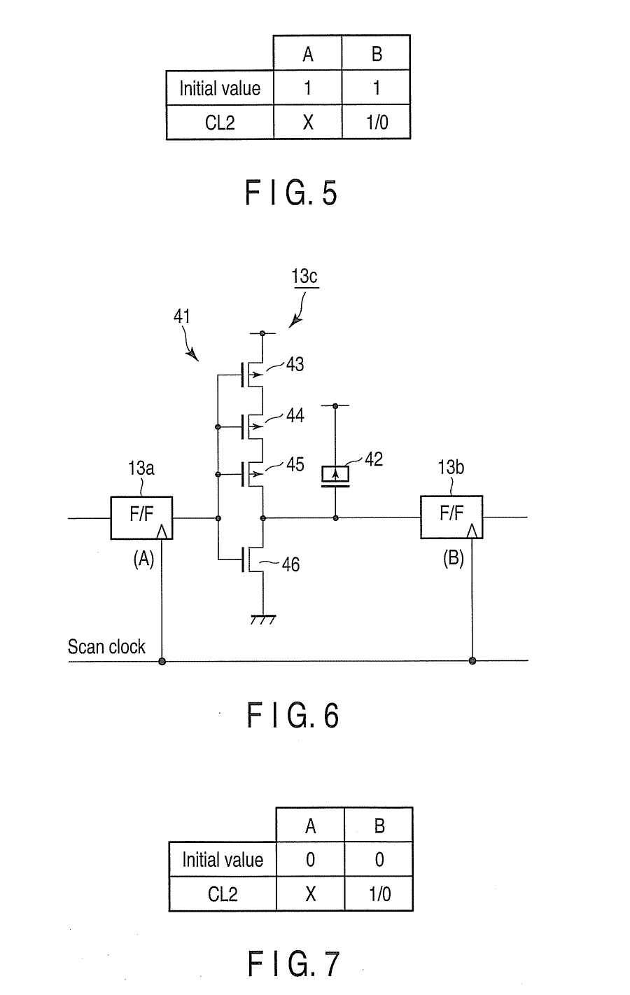

Next, the operation of the above configuration in a test will be explained concretely with reference to FIG. 5. Here, let data items held in the first and second flip-flop circuits 13a, 13b be A and B, respectively.

First, initial values are set in the flip-flop circuits 13a, 13b in synchronization with a scan clock signal (Scan clock). In this case, A and B are set to data “1” and “1”, respectively. In this state, the NMOS capacitor 32 is charged.

Next, the first clock pulse CL1 is input to the first flip-flop circuit 13a and second flip-flop circuit 13b, causing data “1” set in the flip-flop circuit 13a to be output to the inverter circuit 31 in synchronization with the first clock pulse CL1. When data “1” is input to the inverter circuit 31, the charge charged in the NMOS capacitor 32 starts to discharge via the NMOSs 34, 35, 36.

Next, the second clock pulse CL2 is input to the first flip-flop circuit 13a and second flip-flop circuit 13b, causing the second flip-flop circuit 13b to latch data (the potential at the NMOS capacitor 32) output from the inverter circuit 31 in synchronization with the second clock pulse CL2. At this time, when the current driving capability of the NMOSs 34, 35, 36 of the inverter circuit 31 is sufficiently high, the NMOSs 34, 35, 36 of the inverter circuit 31 discharge the charge charged in the NMOS capacitor 32. After the output (the potential at the NMOS capacitor 32) of the inverter 31 has reached data “0”, the second clock pulse CL2 is input to the second flip-flop circuit 13b. As a result, the data held in the second flip-flop circuit 13b is changed from data “1” to data “0”.

When the current driving capability of the NMOSs 34, 35, 36 of the inverter circuit 31 is low, the second clock pulse CL2 is input to the second flip-flop circuit 13b before the NMOSs 34, 35, 36 of the inverter circuit 31 discharge the charge charged in the NMOS capacitor 32. As a result, the second flip-flop circuit 13b does not latch data “0” output from the first flip-flop circuit 13a. Therefore, the data held in the second flip-flop circuit 13b remains at data “1”.

Then, the pulse interval T between the first clock pulse CL1 and second clock pulse CL2 is adjusted and the operations as described above are carried out. For example, the above operations are performed as the pulse interval T is changed so as to decrease gradually. As a result, the current driving capability of the NMOS transistors (NMOSs 34, 35, 36) included in the inverter 31 can be evaluated by monitoring the pulse interval T in which the data in the second flip-flop circuit 13b does not change.

With the test circuit including the inverter circuit 31 and NMOS capacitor 32 shown in FIG. 4, the current driving capability of the NMOSs included in a function block arranged near the test circuit can be evaluated.

Next, an example of the test circuit will be explained with reference to FIG. 6. FIG. 6 shows a test circuit for monitoring the current driving capability of a PMOS.

The logic circuit 13c of the test circuit is composed of an inverter circuit 41 and a PMOS capacitor 42. The inverter 41 is composed of, for example, three PMOSs 43, 44, 45 and a NMOS 46 connected between a power supply and ground. The number of PMOSs is not limited to three. That is, the number of PMOSs has only to be set so as to achieve an operation speed at which the operation of the inverter circuit 41 and PMOS capacitor 42 can be monitored sufficiently in the interval between the first and second clock pulses CL1, CL2.

The gates of the PMOSs 43, 44, 45 and NMOS 46 are connected to the output end of the first flip-flop circuit 13a. The PMOS capacitor 42 is connected between the connection node of PMOS 45 and NMOS 46 and a power supply potential. The connection node of PMOS 45 and NMOS 46 is further connected to the input end of the second flip-flop circuit 13b.

Next, the operation of the above configuration in a test will be explained concretely with reference to FIG. 7. Here, let data items held in the first and second flip-flop circuits 13a, 13b be A and B, respectively.

First, initial values are set in the flip-flop circuits 13a, 13b in synchronization with a scan clock signal (Scan clock). In this case, A and B are set to data “0” and “0”, respectively. In this state, the PMOS capacitor 42 has not been charged.

Next, data “0” set in the flip-flop circuit 13a is output to the inverter circuit 41 in synchronization with the first clock pulse CL1. When data “0” has been input to the inverter circuit 41, the PMOS capacitor 42 starts to charge via the PMOSs 43, 44, 45.

Next, the second flip-flop circuit 13b latches data (the potential at the PMOS capacitor 42) output from the inverter circuit 31 in synchronization with the second clock pulse CL2. At this time, when the current driving capability of the PMOSs 43, 44, 45 of the inverter circuit 41 is sufficiently high, the PMOSs 43, 44, 45 of the inverter circuit 41 charge the PMOS capacitor 42. After the output (the potential at the PMOS capacitor 42) of the inverter 41 has reached data “1”, the second clock pulse CL2 is input to the second flip-flop circuit 13b. As a result, the data held in the second flip-flop circuit 13b is changed from data “0” to data “1”.

When the current driving capability of the PMOSs 43, 44, 45 of the inverter circuit 41 is low, the second clock pulse CL2 is input to the second flip-flop circuit 13b before the PMOSs 43, 44, 45 of the inverter circuit 41 charge the PMOS capacitor 42. As a result, the second flip-flop circuit 13b does not latch data “1” output from the first flip-flop circuit 13a. Therefore, the data held in the second flip-flop circuit 13b remains at data “0”.

Then, the pulse interval T between the first clock pulse CL1 and second clock pulse CL2 is adjusted and the operations as described above are carried out. For example, the above operations are performed as the pulse interval T is changed so as to decrease gradually. As a result, the current driving capability of the PMOS transistors (PMOSs 43, 44, 45) included in the inverter 31 can be evaluated by monitoring the pulse interval T in which the data in the second flip-flop circuit 13b does not change.

With the test circuit including the inverter circuit 31 and PMOS capacitor 42 shown in FIG. 6, the current driving capability of the PMOSs included in a function block arranged near the test circuit can be evaluated.

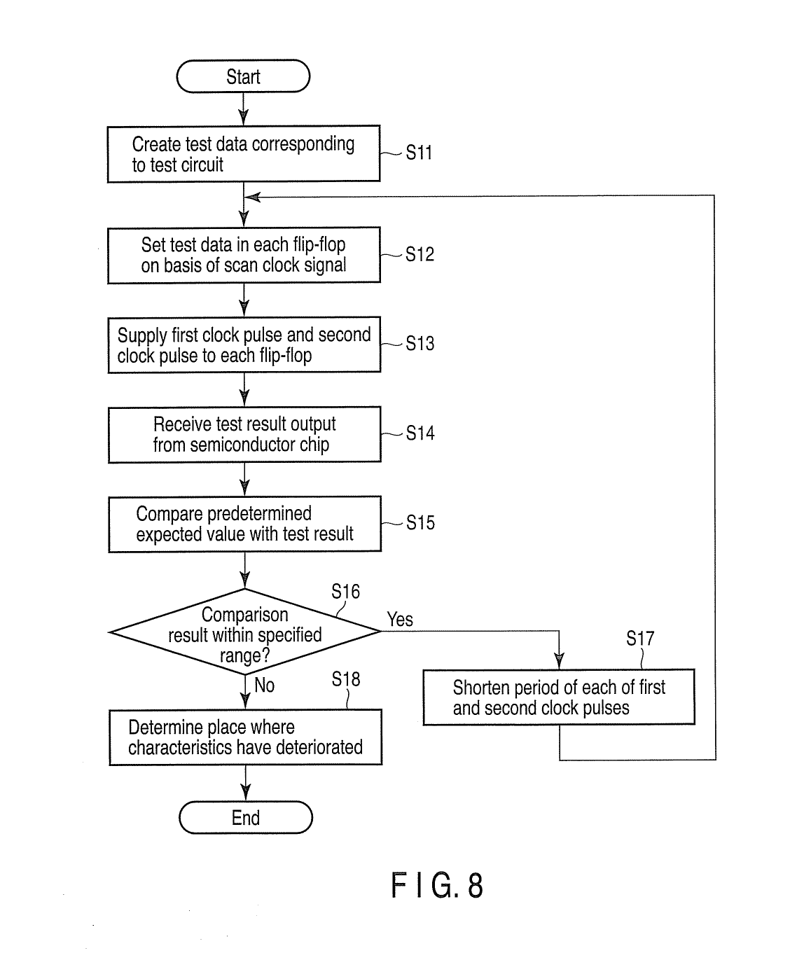

FIG. 8 is a flowchart to explain an operation of the test device 51. In a test, first, the test device 51 creates test data corresponding to a test circuit included in the semiconductor chip 11 (S11). That is, test data is created according to each of the test circuits shown in FIGS. 3, 4, and 5. Thereafter, the test data is set in each of the flip-flop circuits as an initial value in synchronization with a scan clock signal (Scan clock) (S12).

Then, as described above, the logic circuit included in the test circuit is tested using the first and second clock pulses CL1, CL2 (S13). Then, for example, on the basis of the scan clock signal (Scan clock), the data in each of the flip-flop circuits including the second flip-flop circuit 13b is transferred to the test device 51 (S14). The data transferred from the second flip-flop circuit 13b is compared with an expected value previously set according to test data (S15). It is determined whether the comparison result is within a preset reference value (S16). When the result has shown that the comparison result is within the reference value, the pulse interval between the first and second clock pulses CL1, CL2 is made shorter and the test data is set in each of the flip-flop circuits and the above operation is repeated (S12 to S15).

In step S16, when the comparison result has exceeded the preset reference value, a place where the characteristics have deteriorated in the semiconductor chip 11 is determined on the basis of the data transferred to the test device 51 (S18). Specifically, for example, when the text circuit 13-2 could not obtain a correct output result with the clock signal being at a frequency not lower than 260 MHz and test circuit 13-1 could not obtain a correct output result with the clock signal being at a frequency not lower than 300 MHz, it can be determined that the current driving capability of the transistors in a function block near test circuit 13-2 is lower than the current driving capability of the transistors in a function block near test circuit 13-1 and therefore the operation speed has decreased.

Accordingly, on the basis of the pulse interval between the first and second clock pulses and the test result, the characteristic degradation is mapped according to the semiconductor chip, which makes it possible to determine a place in a function block where the characteristics have deteriorated in the semiconductor chip.

With the embodiment, the delay of the transistors in a function block near the area where the test circuits 13-1, 13-2 are arranged or the current driving capability as a characteristic of an NMOS or a PMOS can be estimated.

Specifically, when data passed through a function block was just checked as in a conventional logic BIST, it was difficult to determine whether the data was the result obtained from the operation of a function set in the function block or the result obtained on the basis of the characteristics of the transistors constituting the function block. However, with the embodiment, the test circuits 13-1, 13-2 of the same configuration are arranged in a specific area of the semiconductor chip 11 and the characteristics of the transistors of a function block near the test circuits 13-1, 13-2 can be evaluated on the basis of the results obtained from the test circuits 13-1, 13-2. Therefore, the characteristics of the function block can be evaluated without the effect of the operation of the logic circuit of the function block.

Furthermore, with the embodiment, each of the test circuits has no test pad and is composed of the first and second flip-flop circuits 13a, 13b and logic circuit 13c, resulting in a much smaller circuit size than that of a conventional TEG. Therefore, an increase in the are occupied by the test circuits on a chip resulting from an increased number of test circuits can be suppressed, enabling an increase in the chip size to be prevented.

In the embodiment, a scan chain has been configured throughout the semiconductor chip. However, the embodiment is not limited to this.

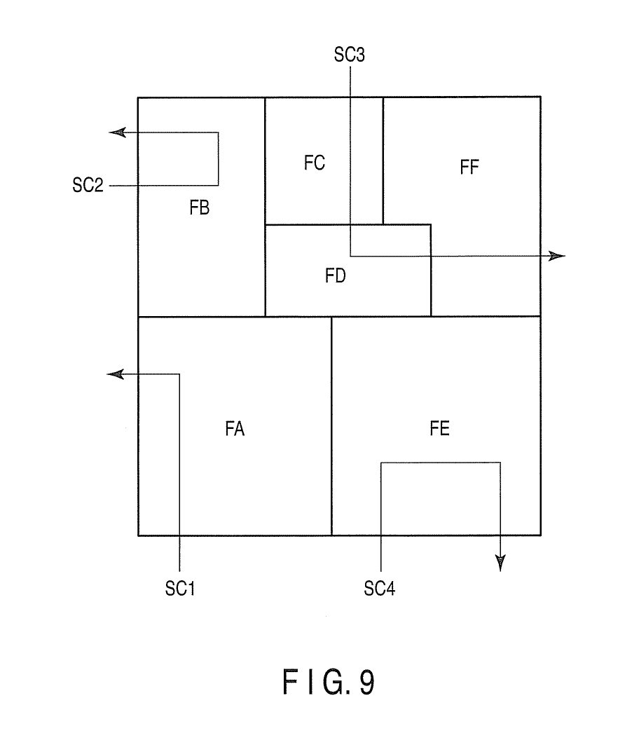

FIG. 9 shows a modification of the embodiment, such as an application-specific integrated circuit (ASIC). In the semiconductor chip 11, function blocks FA to FF, including a memory, a microprocessor, and a digital signal processor (DSP), are arranged. A scan chain including a plurality of test circuits 13-1, 13-2 (not shown) is arranged in every block or in every two or more blocks. That is, scan chain SC1 is arranged in function block FA, scan chain SC2 is arranged in function block FB, scan chain SC3 is arranged in function blocks FC, FD, FF, and scan chain SC4 is arranged in function block FE.

With this configuration, the characteristics of a delay circuit or a transistor can be monitored in units of one function block or of two or more function blocks. Therefore, optimum monitoring can be performed according to the configuration of a function block.

In addition, since the length of each of the scan chains is short, it is easy to create test data and check data after a test.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a function block which includes a plurality of transistors;
a test circuit which is arranged in an area near the function block and which includes a first flip-flop circuit, a second flip-flop circuit, and a logic circuit connected between the output of the first flip-flop circuit and the input of the second flip-flop circuit; and
a signal generation circuit configured to generate clock pulses including a first clock pulse and a second clock pulse, the signal generation circuit being capable of controlling a pulse interval between the first clock pulse and the second clock pulse,
wherein, in a test, the first flip-flop circuit outputs data in synchronization with the first clock pulse of the signal generation circuit and the second flip-flop circuit latches data in synchronization with the second clock pulse of the signal generation circuit.

2. The semiconductor integrated circuit according to claim 1, wherein the logic circuit is a plurality of inverter circuits connected in series.

3. The semiconductor integrated circuit according to claim 1, wherein the test circuit includes a capacitor circuit connected between the input of the second flip-flop circuit and ground potential.

4. The semiconductor integrated circuit according to claim 3, wherein the logic circuit includes at least one inverter circuit and a first-conductivity-type MOS transistor electrically connected between the input of the second flip-flop circuit and ground potential.

5. The semiconductor integrated circuit according to claim 1, further comprising a capacitor circuit connected between the input of the second flip-flop circuit and a power supply potential.

6. The semiconductor integrated circuit according to claim 5, wherein the logic circuit includes at least one inverter circuit and a second-conductivity-type MOS transistor electrically connected between the input of the second flip-flop circuit and power supply potential.

7. The semiconductor integrated circuit according to claim 1, wherein the first flip-flop circuit and the second flip-flop circuit are connected to a flip-flop circuit provided at each of the input end and output end of the function block, respectively.

8. The semiconductor integrated circuit according to claim 1, wherein the signal generation circuit comprises:
a multiplier circuit which multiplies a clock signal; and
a selector which selects the pulse interval from the multiplied clock pulses supplied from the multiplier circuit.

9. The semiconductor integrated circuit according to claim 1, wherein the function block and the test circuit are included in a scan chain.

10. A semiconductor integrated circuit comprising:
a plurality of function blocks each of which includes a plurality of transistors;
at least one scan chain which includes at least one of the function blocks;
a test circuit which is included in the at least one scan chain and arranged in an area near the function block and which includes a first flip-flop circuit, a second flip-flop circuit, and a logic circuit connected between the output of the first flip-flop circuit and the input of the second flip-flop circuit; and
a signal generation circuit configured to generate clock pulses including a first clock pulse and a second clock pulse, the signal generation circuit being capable of controlling a pulse interval between the first clock pulse and the second clock pulse,
wherein, in a test, the first flip-flop circuit outputs data in synchronization with the first clock pulse of the signal generation circuit and the second flip-flop circuit latches data in synchronization with the second clock pulse of the signal generation circuit.

11. The semiconductor integrated circuit according to claim 10, wherein the logic circuit is a plurality of inverter circuits connected in series.

12. The semiconductor integrated circuit according to claim 10, wherein the test circuit includes a capacitor circuit connected between the input of the second flip-flop circuit and ground potential.

13. The semiconductor integrated circuit according to claim 12, wherein the logic circuit includes at least one inverter circuit and a first-conductivity-type MOS transistor electrically connected between the input of the second flip-flop circuit and ground potential.

14. The semiconductor integrated circuit according to claim 10, further comprising a capacitor circuit connected between the input of the second flip-flop circuit and a power supply potential.

15. The semiconductor integrated circuit according to claim 14, wherein the logic circuit includes at least one inverter circuit and a second-conductivity-type MOS transistor electrically connected between the input of the second flip-flop circuit and power supply potential.

16. The semiconductor integrated circuit according to claim 10, wherein the first flip-flop circuit and the second flip-flop circuit are connected to a flip-flop circuit provided at each of the input end and output end of the function block, respectively.

17. The semiconductor integrated circuit according to claim 10, wherein the signal generation circuit comprises:
a multiplier circuit which multiplies a clock signal; and
a selector which selects the pulse interval from the multiplied clock pulses supplied from the multiplier circuit.

18. A method of testing a semiconductor integrated circuit, the method comprising:
causing a first flip-flop circuit to hold test data;
supplying a first clock pulse to the first flip-flop circuit and transferring the test data held in the first flip-flop circuit to a test circuit including a logic circuit;
supplying a second clock pulse to the second flip-flop circuit and transferring the data output from the test circuit to the second flip-flop circuit;
comparing the data transferred to the second flip-flop circuit with a predetermined expected value; and
when the comparison result is within a reference value, shortening the period of the first clock pulse and that of the second clock pulse, and repeating the process of supplying the first clock pulse to the first flip-flop circuit up to the process of comparing the data transferred to the second flip-flop circuit with the predetermined expected value.

19. The method according to claim 18, further comprising: determining a place where the characteristics of a transistor on a chip have deteriorated when the comparison result has exceeded the reference value.
